(19) United States
(12) Patent Application Publication
(10) Pub. No.: US 2023/0070676 A1
(43) Pub. Date: Mar. 9, 2023

(54) CHARGER CIRCUIT AND CHARGING CONTROL METHOD

(71) Applicant: Richtek Technology Corporation, Zhubei City (TW)

(72) Inventors: Hsuan-Kai Wang, Hsinchu (TW); Hsien-Chih She, Hsinchu (TW); Po-Cheng Liu, Hsinchu (TW)

(21) Appl. No.: 17/840,556

(22) Filed: Jun. 14, 2022

(30) Foreign Application Priority Data
Sep. 9, 2021 (TW) 110133556

(51) Int. Cl. H02J 7/00; H02J 7/04; G01R 31/3835

(52) U.S. Cl. CPC H02J 7/007182; G01R 31/3835; H02J 7/04; H02J 7/0047

(57) ABSTRACT

A charger circuit includes: a power stage circuit configured to operate at least one power switch according to an operation signal, so as to convert an input power to a charging power to charge a battery; a control circuit coupled to the power stage circuit and configured to generate the operation signal according to a current feedback signal and a voltage feedback signal; a voltage feedback circuit configured to compare a voltage sensing signal related to a charging voltage of the charging power with a voltage reference level, so as to generate the voltage feedback signal; a battery core voltage drop sensing circuit coupled to a battery core of the battery and configured to sense a battery core voltage drop of the battery core, so as to generate a battery core voltage drop sensing signal; and an adjustment circuit coupled to the battery core voltage drop sensing circuit and configured to generate an adjustment signal according to the battery core voltage drop sensing signal, so as to adaptively adjust the voltage reference level.

### CROSS REFERENCE

The present invention claims priority to TW 110133556 filed on Sep. 9, 2021.

### BACKGROUND OF THE INVENTION

### Field of Invention

The present invention relates to a charger circuit; particularly, it relates to a charger circuit and a charging control method capable of shortening the charging time by adaptive adjustment of a voltage reference level.

### Description of Related Art

Please refer to FIG. 1A. FIG. 1A shows a schematic diagram of a conventional charger circuit. The conventional charger circuit 10 includes a control circuit 11, a power stage circuit 12 and a feedback circuit 13. The power stage circuit 12 is configured to operate power switches QA and QB therein according to operation signals UG and LG, so as to control the conduction state of an inductor L to convert an input power Vin into a charging power Vch to charge a battery 19. The charging power Vch corresponds to a charging voltage Vbat and a charging current Ibat. The control circuit 11 is coupled to the power stage circuit 12 for generating the operation signals UG and LG according to a feedback signal FB.

The feedback circuit 13 is configured to generate the feedback signal FB according to the charging current Ibat and the charging current Vbat. The power stage circuit 12 includes the power switches QA and QB, and the inductor L. The power switch QA is coupled between the input power Vin and a first terminal LX1 of the inductor L, and the power switch QB is coupled between a ground potential GND and the first terminal LX1 of the inductor L. The operation signals UG and LG are configured to control the power switch QA and the power switch QB respectively, so as to switch the first terminal LX1 of the inductor L between the input power Vin and the ground potential GND. The charging power Vch is coupled to a second terminal LX2 of the inductor L, thereby converting the input power Vin into the charging power Vch to charge the battery 19.

FIG. 1B shows a characteristic curve depicting the relationships between the charging voltage Vbat and time (as indicated by the black thick solid line in FIG. 1B) and between the charging current Ibat and time (as indicated by the black thick dashed line in FIG. 1B) of the conventional charger circuit. As shown in FIG. 1B, in a first period from time point t0 to time point t1, the charging current Ibat of the conventional charger circuit 10 is regulated to a constant current Ict to charge the battery 19; in a second period from time point t1 to time point t2, the charging voltage Vbat is regulated to a constant voltage Vct to charge the battery 19.

In the second period wherein the charging voltage Vbat is regulated to the constant voltage Vct, the charging current Ibat continues charging a battery core 191 inside the battery 19, and the voltage of the battery core 191 increases gradually. Because the charging voltage Vbat is regulated to the constant voltage Vct, the voltage drop generated by the charging current Ibat flowing through a resistor Rpr having a chemical resistance in the battery 19 decreases gradually, and the charging current Ibat decreases gradually. When the charging current decreases to a charging current Ibf which is close to or equal to zero current, it indicates that the charging of the battery 19 is complete. In the second period from time point t1 to time point t2, the charging efficiency is lower because the charging current Ibf decreases gradually. A longer period with the lower charging efficiency will lead to a longer charging time.

In view of the above, to overcome the drawback of the prior art, the present invention proposes a charger circuit and a charging control method that can shorten the charging time.

### SUMMARY OF THE INVENTION

From one perspective, the present invention provides a charger circuit, including: a power stage circuit, configured to operate at least one power switch according to an operation signal, so as to convert an input power to a charging power to charge a battery, wherein the charging power includes a charging voltage and a charging current; a control circuit, coupled to the power stage circuit and configured to generate the operation signal according to a current feedback signal and a voltage feedback signal; a current feedback circuit, configured to compare a current sensing signal relevant to the charging current with a current reference level, thereby generating the current feedback signal; a voltage feedback circuit, configured to compare a voltage sensing signal relevant to the charging voltage with a voltage reference level, thereby generating the voltage feedback signal; a battery core voltage drop sensing circuit, coupled to a battery core of the battery and configured to sense a battery core voltage drop of the battery core, thereby generating a battery core voltage drop sensing signal; and an adjustment circuit, coupled to the battery core voltage drop sensing circuit and configured to generate an adjustment signal according to the battery core voltage drop sensing signal, so as to execute an adaptive adjustment of the voltage reference level.

From another perspective, the present invention provides a charging control method, configured to convert an input power into a charging power to charge a battery, the charging control method comprises: generating an operation signal according to a current feedback signal and voltage feedback signal; operating at least one power switch according to the operation signal, so as to convert the input power into the charging power, wherein the charging power includes a charging voltage and a charging current; wherein the current feedback signal is generated by comparing a current sensing signal relevant to the charging current with a current reference level, and the voltage feedback signal is generated by comparing a voltage sensing signal relevant to the charging voltage with a voltage reference level; and a reference level adjustment procedure, including: sensing a battery core voltage drop of a battery core inside the battery, thereby generating a battery core voltage drop sensing signal; and generating an adjustment signal according to the battery core voltage drop sensing signal, so as to execute an adaptive adjustment of the voltage reference level.

In one embodiment, the adjustment circuit adaptively lower the voltage reference level when the battery core voltage drop sensing signal exceeds a predetermined threshold.

In one embodiment, the adjustment circuit includes a step drop circuit, configured to adjust a step signal to an ENABLE level when the battery core voltage drop sensing signal exceeds the predetermined threshold, so as to indicate that the battery core voltage drop sensing signal exceeds the predetermined threshold, thereby lowering the voltage reference level by a predetermined difference.

In one embodiment, the charger circuit further includes a timer circuit, coupled to the adjustment circuit, wherein when the step signal is at a DISABLE level to indicate that the battery core voltage sensing signal does not exceed the predetermined threshold, the timer circuit is configured to count a time-out period and generate an adjustment-ending signal at an end time point of the time-out period when the step signal is at the DISABLE level, so as to end the adaptive adjustment of the voltage reference level.

In one embodiment, the control circuit generates an adjustment-ending signal when the voltage reference level is not higher than a predetermined lower limit level, so as to end the adaptive adjustment of the voltage reference level.

In one embodiment, the battery core voltage drop sensing circuit includes an analog-to-digital converter circuit, configured to convert the battery core voltage drop in analog form into the battery core voltage drop sensing signal in digital form.

In one embodiment, the power stage circuit includes a switched inductive power stage circuit, a switched capacitive power stage circuit, a low dropout linear regulator or an AC/DC converter circuit.

In one embodiment, the charging control method further includes setting an activation signal to an ENABLE level, so as to start up the reference level adjustment procedure.

In one embodiment, the charging control method further includes: setting the voltage reference level to the predetermined lower limit level when a protection signal is at a DISABLE level, so as to end the reference level adjustment procedure.

In one embodiment, the step of adaptively lowering the voltage reference level when the battery core voltage drop sensing signal exceeds the predetermined threshold further includes: after the voltage reference level is lowered by the predetermined difference, maintaining the lowered voltage reference level for a predetermined period of time

The present invention has an advantage that by adjusting the voltage reference level lower, the present invention can shorten the charging time.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a schematic diagram of a conventional charger circuit.

FIG. 1B shows a characteristic curve depicting the relationships between the charging voltage and time and between the charging current and time of the conventional charger circuit.

FIG. 2A is a schematic circuit block diagram showing a charging circuit according to one embodiment of the present invention.

FIG. 2B shows a characteristic curve depicting the relationships between the charging voltage and time and between the charging current and time of the present invention, and between the charging current and time of the conventional charger circuit.

FIG. 2C shows a characteristic curve depicting the relationships between the voltage drop of the battery core and time and between the charging current and time of the charging circuit according to one embodiment of the present invention and the prior art.

FIGS. 3A-3F are flowcharts showing steps of a charging control method according to several embodiments of the present invention.

FIG. 4 is a flowchart showing the steps of a charging control method according to one embodiment of the present invention.

FIG. 5 is a flowchart showing the steps of a charging control method according to another embodiment of the present invention.

FIG. 6 is a flowchart showing the steps of a charging control method according to a still other embodiment of the present invention.

FIGS. 7A-7K shows embodiments of synchronous or asynchronous buck, boost, inverting, inverting-boost and flyback type switched inductive power stage circuits.

FIG. 8 shows an embodiment of a switched capacitive power stage circuit.

FIG. 9 shows an embodiment of a low dropout linear regulator.

FIG. 10 shows an embodiment of an AC/DC converter circuit.

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

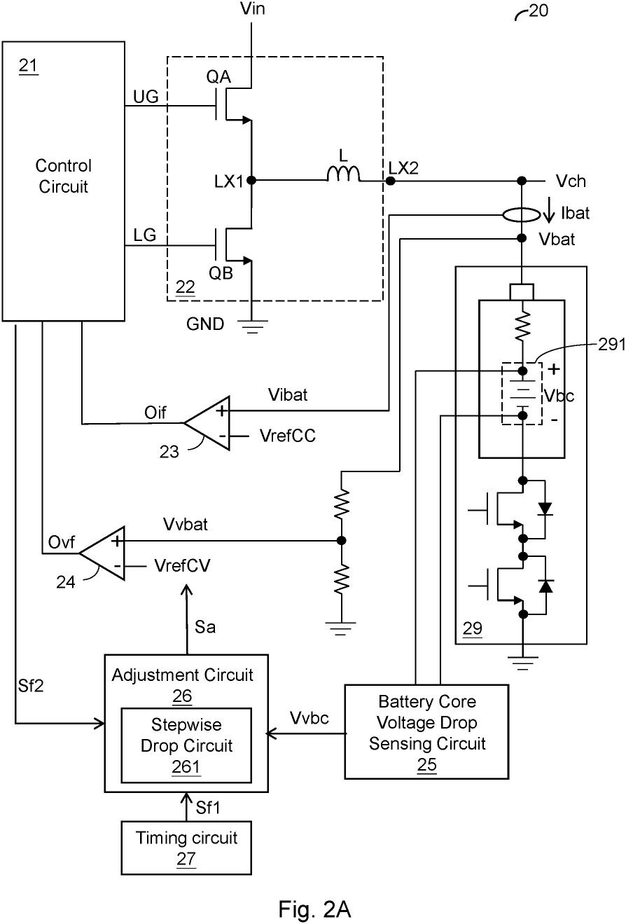

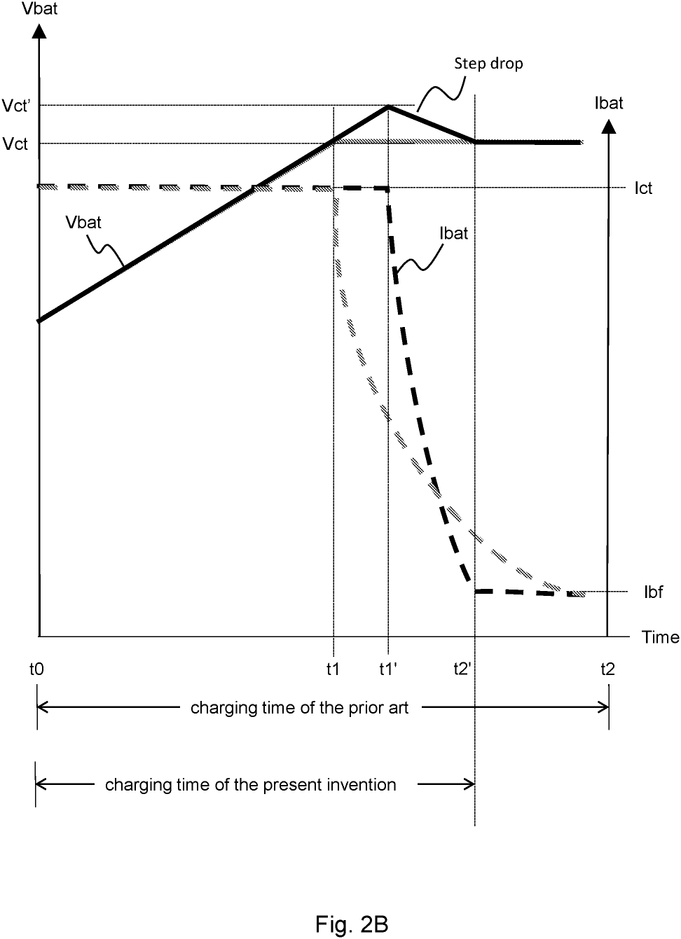

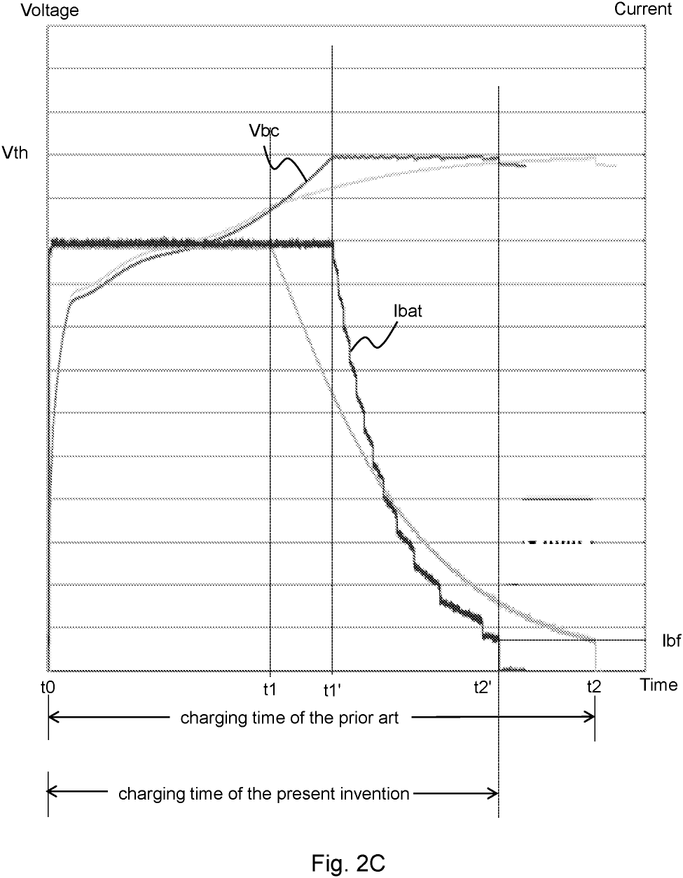

FIG. 2A is a schematic circuit block diagram of a charging circuit according to one embodiment of the present invention. As shown in FIG. 2A, the charging circuit 20 of the present invention includes a control circuit 21, a power stage circuit 22, a current feedback circuit 23, a voltage feedback circuit 24, a battery core voltage drop sensing circuit 25, an adjustment circuit 26 and a timing circuit 27. The power stage circuit 22 is configured to operate power switches QA and QB in response to corresponding operation signals UG and LG, so as to convert the input power Vin to the charging power Vch for charging the battery 29. The charging power Vch corresponds to the charging voltage Vbat and the charging current Ibat. The control circuit 21 is coupled to the power stage circuit 22 to generate the operation signals UG and LG according to a current feedback signal Oif and a voltage feedback signal Ovf.

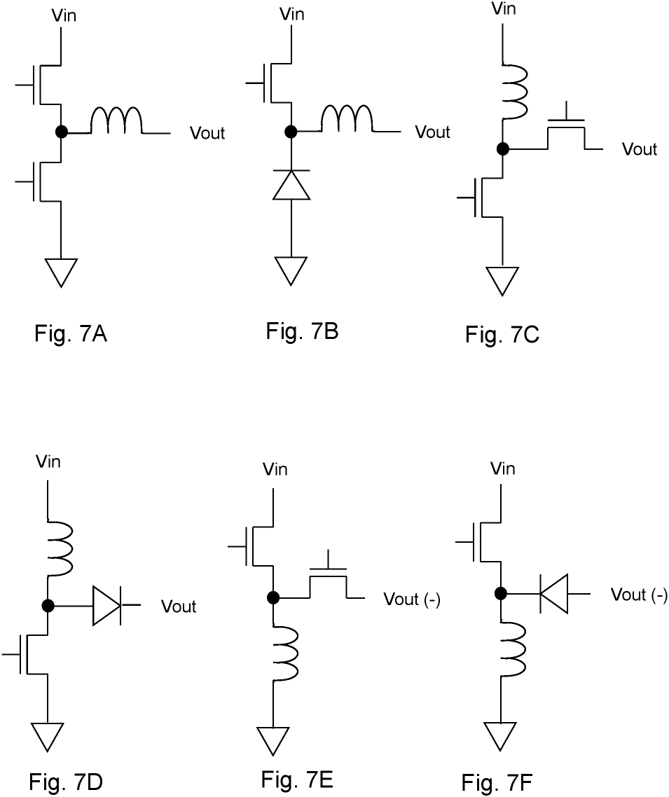

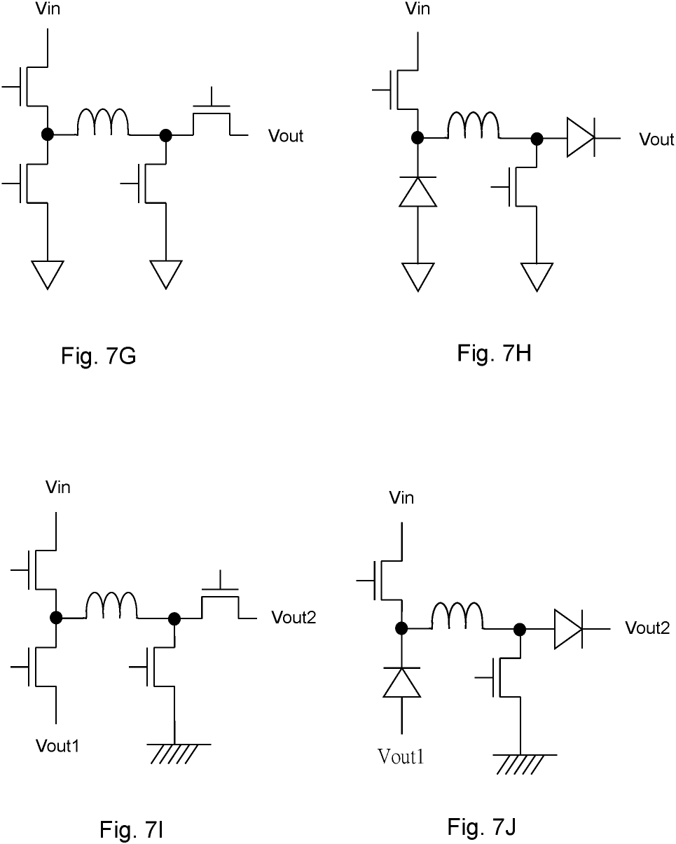

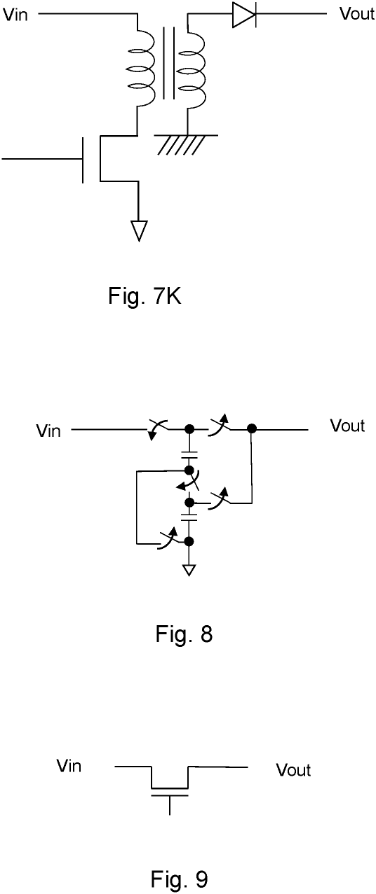

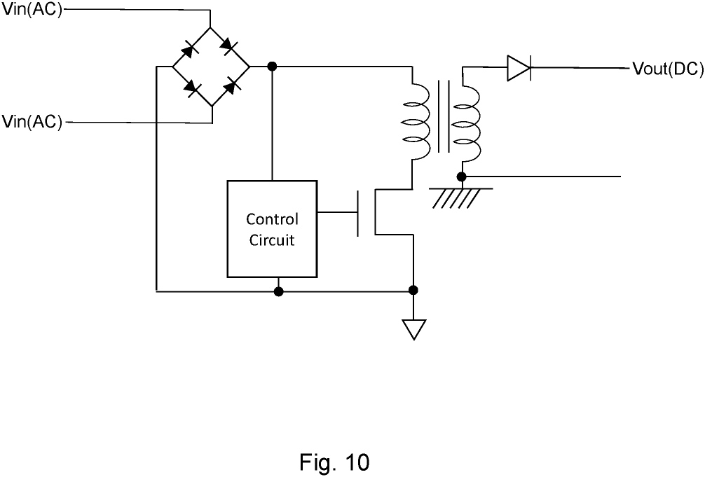

The power stage circuit 22 shown in FIG. 2A is a step-down (buck) power stage circuit in a switched inductive power stage circuit. According to the present invention, the power stage circuit 22 is not limited to a switched inductive power stage circuit; it can instead be a switched capacitive power stage circuit, a low dropout linear regulator or an AC/DC converter circuit. FIGS. 7A-7K shows embodiments of synchronous or asynchronous buck, boost, inverting, inverting-boost and flyback type switched inductive power stage circuits. FIG. 8 shows an embodiment of a switched capacitive power stage circuit. FIG. 9 shows an embodiment of a low dropout linear regulator. FIG. 10 shows an embodiment of an AC/DC converter circuit.

The current feedback circuit 23 is configured to compare a current sensing signal Vibat which is related to the charging current Ibat with a current reference level VrefCC, so as to generate the current feedback signal Oif. The voltage feedback circuit 24 is configured to compare a voltage sensing signal Vvbat which is related to the charging voltage Vbat with a voltage reference level VrefCV, so as to generate the voltage feedback signal Ovf. The battery core voltage drop sensing circuit 25 is coupled to the battery core 291 of the battery 29 to sense the battery core voltage drop Vbc of the battery core 291 and generate a battery core voltage drop sensing signal Vvbc. In one embodiment, the battery core voltage drop sensing circuit 25 includes an analog-to-digital converter circuit (ADC) for converting the battery core voltage drop Vbc in analog form into the battery core voltage drop sensing signal Vvbc in digital form.

The adjustment circuit 26 is coupled to the battery core voltage drop sensing circuit 25 to generate an adjustment signal Sa based on the battery core voltage drop sensing signal Vvbc, so as to adaptively adjust the voltage reference level VrefCV. In one embodiment, the adjustment circuit 26 adaptively lower the voltage reference level VrefCV when the battery core voltage drop sensing signal Vvbc exceeds a predetermined threshold Vth. In one embodiment, the abovementioned predetermined threshold Vth is, for example but not limited to, 4.2 V or 4.4 V. As shown in FIG. 2A, in one embodiment, the adjustment circuit 26 includes a step drop circuit 261 for adjusting a step signal to an ENABLE level when the battery core voltage drop sensing signal Vvbc exceeds the predetermined threshold Vth, to indicate that the battery core voltage drop sensing signal Vvbc exceeds the predetermined threshold Vth, whereby the voltage reference level VrefCV is lowered by a predetermined difference. In one embodiment, the abovementioned predetermined difference is, for example but not limited to, 10 mv. In one embodiment, the adjustment circuit 26 maintains the lowered voltage reference level VrefCV for a predetermined period of time after the voltage reference level VrefCV has been lowered by the predetermined difference. In one embodiment, the aforementioned predetermined time is, for example but not limited to, 32 microseconds (ms) , 64 ms, 128 ms or 256 ms.

The timing circuit 27 is coupled to the adjustment circuit 26. When the step signal is at a DISABLE level, indicating that the battery core voltage drop sensing signal Vvbc does not exceed the predetermined threshold Vth, the timing circuit 27 counts a timeout period. At the end of the timeout period and when the step signal is still at the DISABLED level, the timing circuit 27 generates an adjustment-ending signal Sf1 to end the adaptive adjustment of the voltage reference level VrefCV. In one embodiment, the aforementioned timeout period is, for example but not limited to, 0.5 s or 1 s. When the voltage reference level VrefCV is not higher than a predetermined lower limit level, the control circuit 21 generates an adjustment-ending signal Sf2 to end the adaptive adjustment of the voltage reference level VrefCV.

The power stage circuit 22 includes the power switches QA and QB and the inductor L. The power switch QA is coupled between the input power Vin and a first terminal LX1 of inductor L, while the power switch QB is coupled between the ground potential GND and the first terminal LX1 of inductor L. The operation signals UG and LG respectively control the power switch QA and power switch QB to switch the first terminal LX1 of the inductor L between the input power Vin and the ground potential GND. The charging power Vch is coupled to a second terminal LX2 of the inductor L to convert the input power Vin to the charging power Vch so as to charge the battery 29.

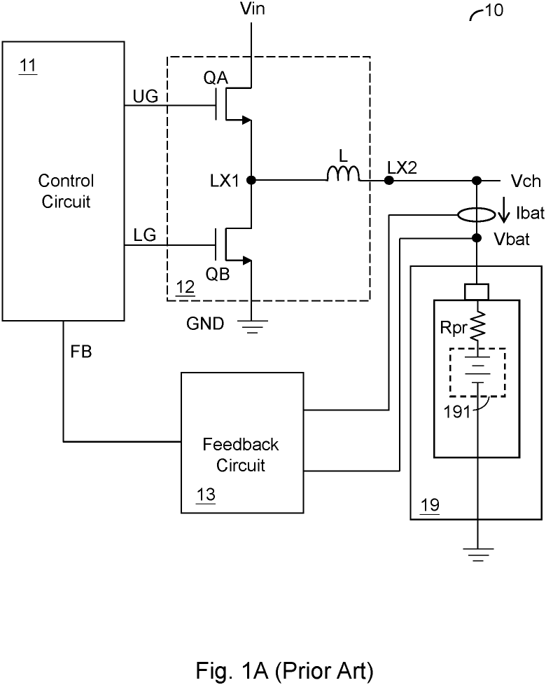

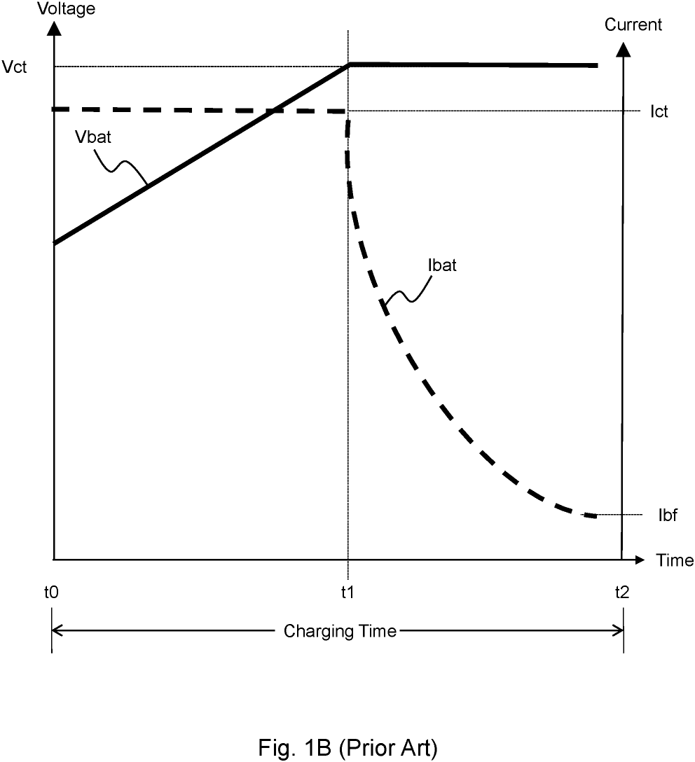

FIG. 2B shows a characteristic curve depicting the relationships between the charging voltage and time and between the charging current and time of the present invention, and between the charging current and time of the conventional charger circuit. FIG. 2C shows a characteristic curve depicting the relationships between the voltage drop of the battery core and time and between the charging current and time of the charging circuit according to one embodiment of the present invention and the prior art. In FIGS. 2B and 2C, the grey line is the prior art and the black line is the present invention. As shown in FIGS. 2B and 2C, the time required to charge the battery by the charging circuit of the present invention is significantly shorter than that of the prior art in FIG. 1A.

As shown in FIG. 2B, in the prior art, as mentioned above, the charging efficiency is low during the second period between time point t1 and time point t2 due to the decrease of the charging current Ibat; and this low efficiency causes the second period to be long, which results in a long total charging time.

Still referring to FIG. 2B, in particular the curve of the charging voltage Vbat (indicated by the thick black solid line in FIG. 2B) and the curve of the charging current Ibat (indicated by the thick black dotted line in FIG. 2B) which are under control by the charging circuit according to the present invention, in the period from time point t0 to time point t1', the feedback control is dominated by the current feedback circuit 23, so the charging current Ibat is regulated to the constant current Ict to charge the battery 19. During the period from time point t1' to time point t2', the feedback control is dominated by the voltage feedback circuit 14, and in this period, the voltage reference level VrefCV is adaptively adjusted in a step drop manner, that is, the voltage reference level VrefCV is lowered by one predetermined difference each time, so that the charging voltage Vbat gradually drops until the voltage reference level VrefCV is not higher than the predetermined lower limit level, and when the voltage reference level VrefCV is not higher than the predetermined lower limit level, the control circuit 21 generates the adjustment-ending signal Sf2 to end the adaptive adjustment of the voltage reference level VrefCV and regulate the charging voltage Vbat to a constant voltage Vct.

Comparing the characteristic curve according to the present invention with the characteristic curve according to the prior art, it can be found that in the period between time points t1 and t1' , the present invention sets the voltage reference level VrefCV at the levl Vct', which is higher than the level Vct; hence, during this period, the charging circuit according to the present invention can charge the battery 19 with a higher constant current Ict as compared to the prior art, so that the charging time can be shortened.

FIG. 2C shows a characteristic curve depicting the relationships between the voltage drop of the battery core and time and between the charging current and time of the charging circuit according to one embodiment of the present invention and the prior art. As mentioned above, the charging circuit according to the present invention has a shorter charging time compared to the prior art. When the battery core voltage drop sensing signal Vvbc related to the battery core voltage drop Vbc exceeds the predetermined threshold Vth, the voltage reference level VrefCV is lowered by one predetermined difference and the lowered voltage reference level VrefCV is for example maintained for a predetermined period of time, and the charging operation continues. When the battery core voltage drop sensing signal Vvbc exceeds the predetermined threshold Vth again, the voltage reference level VrefCV is lowered by one predetermined difference again and the lowered voltage reference level VrefCV is maintained for a predetermined period of time. Such operation repeats until the voltage reference level VrefCV is not higher than the predetermined lower limit level, and then the reference level adjustment procedure is ended. The aforementioned embodiment is an adaptive step-down adjustment of the voltage reference level VrefCV.

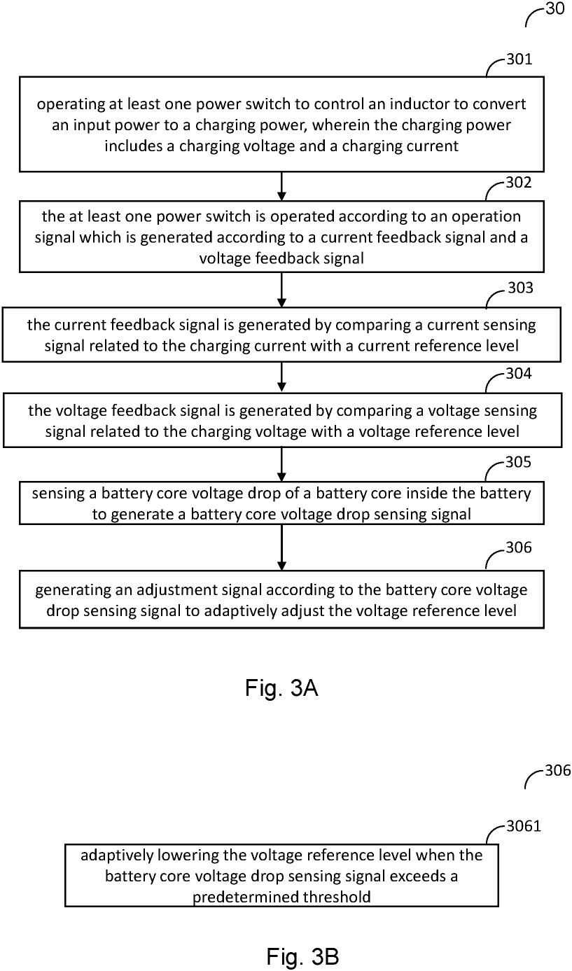

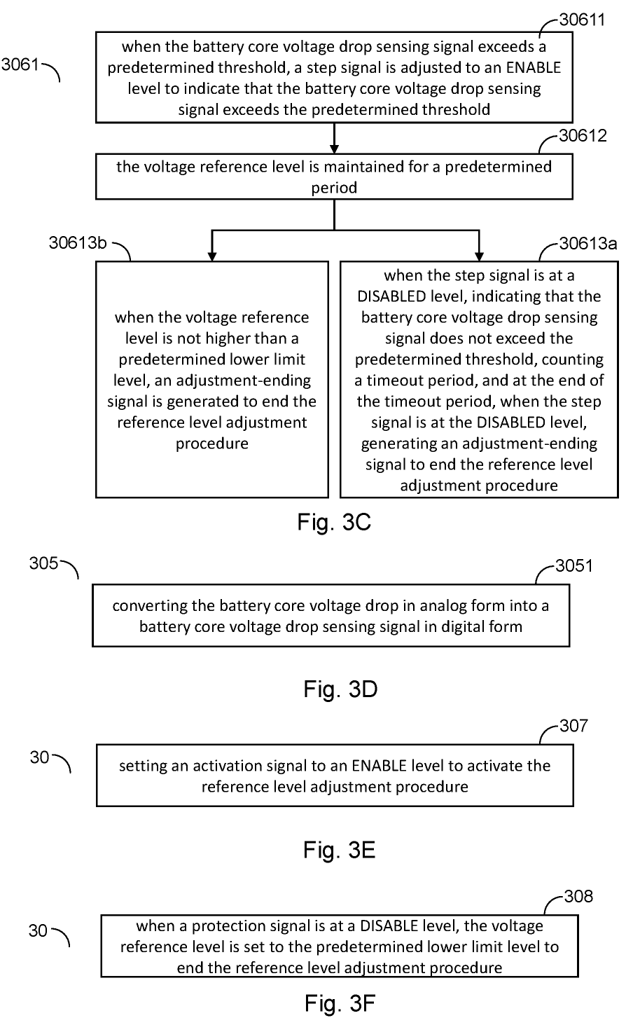

FIGS. 3A-3F are flowcharts showing steps of a charging control method according to several embodiments of the present invention. As shown in FIG. 3A, the charging control method 30 of the present invention includes: Step 301, operating at least one power switch to control an inductor to convert an input power to a charging power, wherein the charging power includes a charging voltage and a charging current. Step 302, the at least one power switch is operated according to an operation signal which is generated according to a current feedback signal and a voltage feedback signal. Step 303, the current feedback signal is generated by comparing a current sensing signal related to the charging current with a current reference level. Step 304, the voltage feedback signal is generated by comparing a voltage sensing signal related to the charging voltage with a voltage reference level. A reference level adjustment procedure includes Step 305 and Step 306, wherein in Step 305, a battery core voltage drop of a battery core inside the battery is sensed to generate a battery core voltage drop sensing signal, and in Step 306, an adjustment signal is generated according to the battery core voltage drop sensing signal to adaptively adjust the voltage reference level.

As shown in FIG. 3B, in one embodiment, Step 306 may include Step 3061, wherein when the battery core voltage drop sensing signal exceeds a predetermined threshold, the voltage reference level is adaptively lowered. As shown in FIG. 3C, in one embodiment, Step 3061 may include: Step 30611, when the battery core voltage drop sensing signal exceeds the predetermined threshold, a step signal is adjusted to an ENABLE level to indicate that the battery core voltage drop sensing signal exceeds the predetermined threshold, and the voltage reference level is lowered by a predetermined difference. Next, in Step 30612, the voltage reference level is maintained for a predetermined period. Thereafter in one embodiment, the process proceeds to Step 30613a: when the step signal is at a DISABLED level, indicating that the battery core voltage drop sensing signal does not exceed the predetermined threshold, counting a timeout period, and at the end of the timeout period, when the step signal is at the DISABLED level, generating an adjustment-ending signal to end the reference level adjustment procedure. In another embodiment, the process proceeds to Step 30613b: when the voltage reference level is not higher than a predetermined lower limit level, an adjustment-ending signal is generated to end the reference level adjustment Step.

As shown in FIG. 3D, Step 305 may include Step 3051: converting the battery core voltage drop in analog form into a battery core voltage drop sensing signal in digital form. As shown in FIG. 3E, the charging control method 30 of the present invention may further include Step 307: setting an activation signal to an ENABLE level to activate the reference level adjustment Step. As shown in FIG. 3F, the charging control method 30 of the present invention may further include Step 308: when a protection signal is at a DISABLE level, the voltage reference level is set to the predetermined lower limit level to end the reference level adjustment Step.

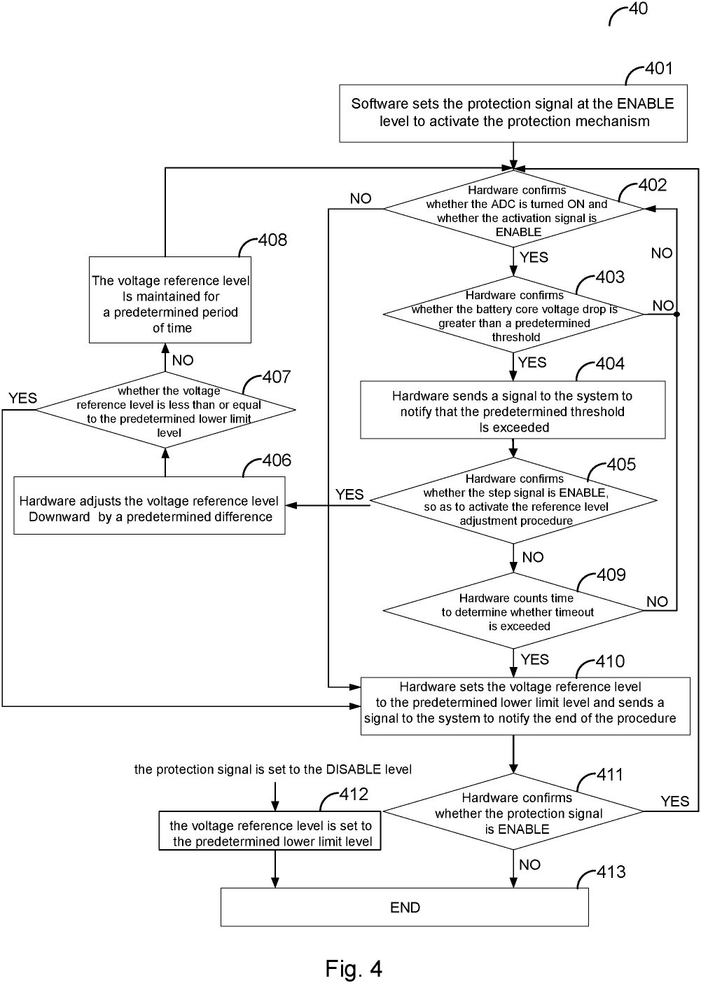

FIG. 4 is a flowchart showing Steps of a charging control method according to one embodiment of the present invention. As shown in FIG. 4, the charging control method 40 of the present invention may include: Step 401, setting the protection signal at the ENABLE level by software to activate the protection mechanism. Next, in Step 402, the hardware confirms whether the analog-to-digital conversion circuit (ADC) is turned ON and whether the activation signal related to the channel in the ADC for detecting the voltage drop of the battery is at the ENABLE level. If YES, go to Step 403; if NO, go to Step 410. In Step 403, the hardware confirms whether the voltage drop of the battery core is greater than a predetermined threshold. If YES, go to Step 404; if NO, go back to Step 402. In one embodiment, the abovementioned predetermined threshold is, for example but not limited to, 4.2 V or 4.4 V.

In Step 404, the hardware sends a signal to the system to notify that the predetermined threshold is exceeded. Next, in Step 405, the hardware confirms whether the Step signal is at the ENABLE level, so as to activate the reference level adjustment procedure. If YES, go to Step 406; if NO, go to Step 409. In Step 406, the voltage reference level is adjusted downward by a predetermined difference by the hardware. In one embodiment, the aforementioned predetermined difference is, for example but not limited to, 10 mV. Next, in Step 407, it is confirmed whether the voltage reference level is less than or equal to the predetermined lower limit level. If YES, go to Step 410; if NO, go to Step 408. In Step 408, the voltage reference level is maintained for a predetermined period of time. In one embodiment, the aforementioned predetermined time is, for example but not limited to, 32 ms, 64 ms, 128 ms, or 256 ms. After the end of Step 408, the process returns to Step 402.

In Step 409, the hardware counts time to determine whether a timeout period is exceeded. If YES, go to Step 410; if NO, go back to Step 402. In one embodiment, the abovementioned timeout period is, for example but not limited to, 0.5 s or 1 s. Step 410, the hardware sets the voltage reference level to the predetermined lower limit level and sends a signal to the system to notify the end of the reference level adjustment procedure. Next, in Step 411, the hardware confirms whether the protection signal is at the ENABLE level. If YES, go back to Step 402; if NO, go to Step 413. In another embodiment, in Step 412, when the protection signal is set to the DISABLE level, the voltage reference level is set to the predetermined lower limit level. After that, in Step 413, all procedures are ended.

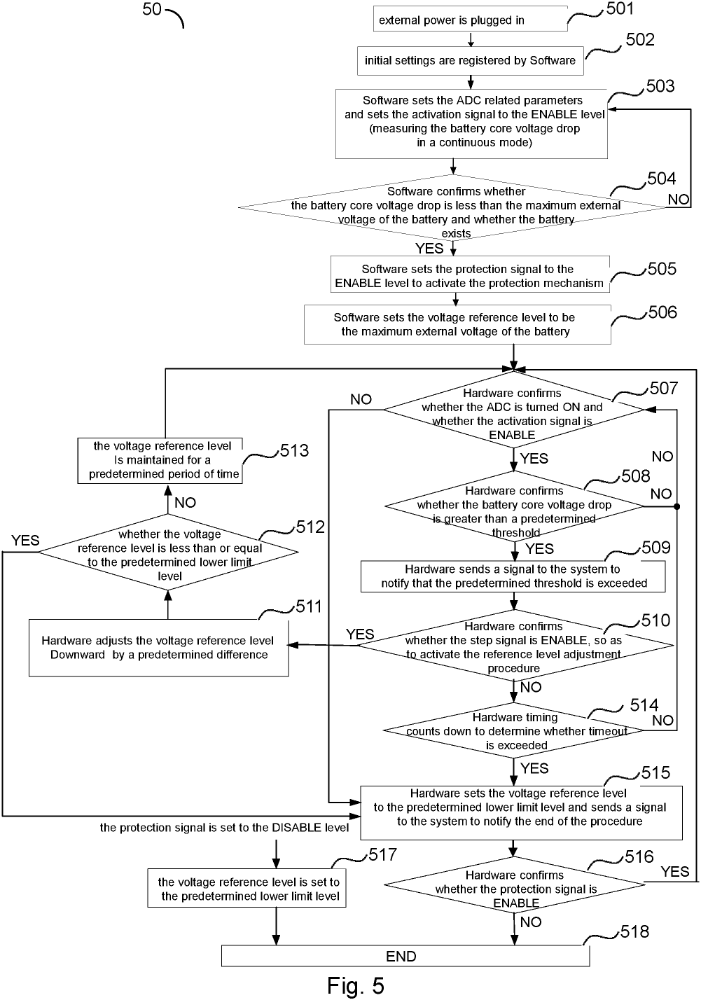

FIG. 5 is a flowchart showing steps of a charging control method according to another embodiment of the present invention. This embodiment uses hardware to implement the charging control method. The difference between this embodiment and the embodiment of FIG. 4 is that the charging control method 50 of one embodiment further includes Steps 501 ~ 506. In Step 501, an external power is plugged in. Next, in Step 502, initial settings are registered by software. In one embodiment, the abovementioned initial setting is, for example but not limited to, the initial settings of the predetermined lower limit level, the predetermined threshold value, the Step signal, the predetermined time, the voltage reference level, etc. In one embodiment, the initial setting of the Step signal is set to the ENABLE level. Then, in Step 503, the software sets the ADC related parameters and sets the activation signal related to the channel in the ADC for detecting the battery core voltage drop to the ENABLE level (i.e., measuring of the battery core voltage drop in a continuous mode). Next, in Step 504, the software confirms whether the battery core voltage drop is less than the maximum external voltage of the battery and whether the battery exists. If YES, go to Step 505; if NO, go back to Step 503. In Step 505, the software sets the protection signal to the ENABLE level to activate the protection mechanism. Next, in Step 506, the voltage reference level is set by the software to be the maximum external voltage of the battery. In one embodiment, the aforementioned maximum external voltage of the battery is, for example but not limited to, 4.7 V. After Step 506 ends, go to Steps 507 ~ 518. Steps 507 ~ 518 are similar to Steps 402 ~ 413 in FIG. 4, so the detailed descriptions thereof are omitted. Another difference between this embodiment and the embodiment of FIG. 4 is that after the end of Step 515, when the software receives the signal, it will set the activation signal to the DISABLE level, the protection signal to the DISABLE level and the voltage reference level to the maximum external voltage of the battery.

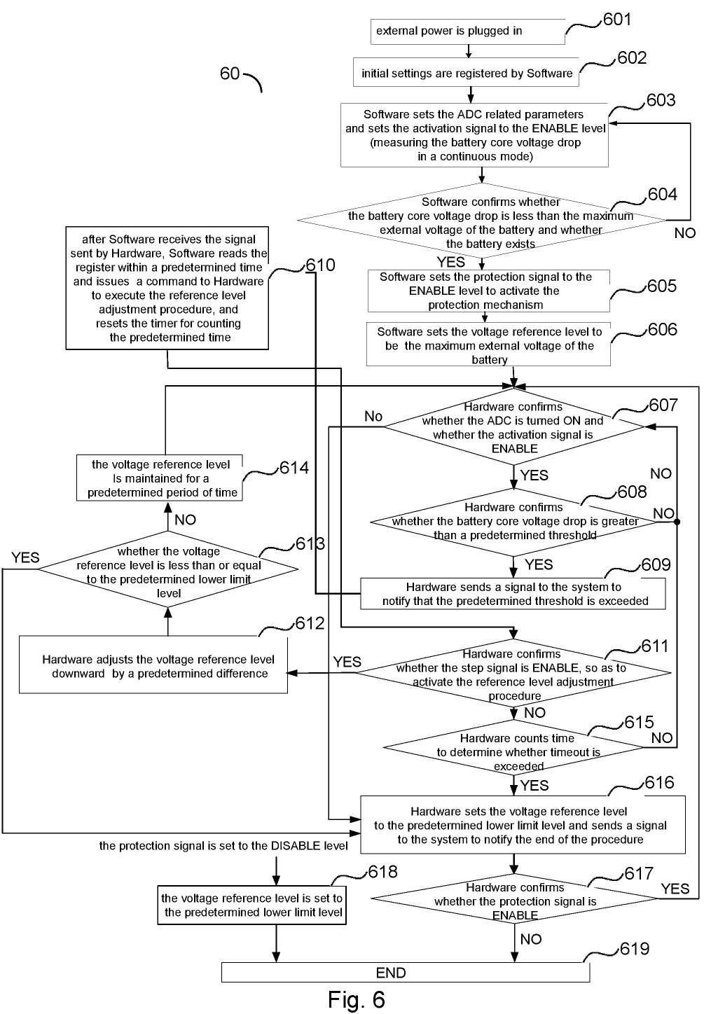

FIG. 6 is a flowchart showing Steps of a charging control method according to another embodiment of the present invention. This embodiment uses the software to issue commands/instructions to the hardware through a communication interface to implement the charging control method. Steps 601~609 and 611~619 are similar to Steps 501~518 in FIG. 5, so the detailed descriptions thereof are omitted. The difference between this embodiment and the embodiment shown in FIG. 5 is that after Step 609 ends, the method proceeds to Step 610. After the software receives the signal sent by the hardware, it reads the register within a predetermined time and issues a command to the hardware to execute the reference level adjustment procedure, and resets the timer for counting the predetermined time. In one embodiment, the abovementioned predetermined time is, for example but not limited to, 0.5 s.

As described above, the present invention provides a charging circuit and a control method thereof, which can shorten the charging time by lowering the voltage reference level.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A charger circuit, comprising:
a power stage circuit, configured to operate at least one power switch according to an operation signal, so as to convert an input power to a charging power to charge a battery, wherein the charging power includes a charging voltage and a charging current;
a control circuit, coupled to the power stage circuit and configured to generate the operation signal according to a current feedback signal and a voltage feedback signal;
a current feedback circuit, configured to compare a current sensing signal relevant to the charging current with a current reference level, thereby generating the current feedback signal;
a voltage feedback circuit, configured to compare a voltage sensing signal relevant to the charging voltage with a voltage reference level, thereby generating the voltage feedback signal;
a battery core voltage drop sensing circuit, coupled to a battery core of the battery and configured to sense a battery core voltage drop of the battery core, thereby generating a battery core voltage drop sensing signal; and
an adjustment circuit, coupled to the battery core voltage drop sensing circuit and configured to generate an adjustment signal according to the battery core voltage drop sensing signal, so as to execute an adaptive adjustment of the voltage reference level.

2. The charger circuit of claim 1, wherein the adjustment circuit adaptively lower the voltage reference level when the battery core voltage drop sensing signal exceeds a predetermined threshold.

3. The charger circuit of claim 2, wherein the adjustment circuit includes a step drop circuit, configured to adjust a step signal to an ENABLE level when the battery core voltage drop sensing signal exceeds the predetermined threshold, so as to indicate that the battery core voltage drop sensing signal exceeds the predetermined threshold, thereby lowering the voltage reference level by a predetermined difference.

4. The charger circuit of claim 3, further comprising a timer circuit, coupled to the adjustment circuit, wherein when the step signal is at a DISABLE level to indicate that the battery core voltage sensing signal does not exceed the predetermined threshold, the timer circuit is configured to count a time-out period and generate an adjustment-ending signal at an end time point of the time-out period when the step signal is at the DISABLE level, so as to end the adaptive adjustment of the voltage reference level.

5. The charger circuit of claim 3, wherein the control circuit generates an adjustment-ending signal when the voltage reference level is not higher than a predetermined lower limit level, so as to end the adaptive adjustment of the voltage reference level.

6. The charger circuit of claim 1, wherein the battery core voltage drop sensing circuit includes an analog-to-digital converter circuit, configured to convert the battery core voltage drop in analog form into the battery core voltage drop sensing signal in digital form.

7. The charger circuit of claim 1, wherein the power stage circuit includes a switched inductive power stage circuit, a switched capacitive power stage circuit, a low dropout linear regulator or an AC/DC converter circuit.

8. A charging control method, configured to convert an input power into a charging power to charge a battery, the charging control method comprises:
generating an operation signal according to a current feedback signal and voltage feedback signal;
operating at least one power switch according to the operation signal, so as to convert the input power into the charging power, wherein the charging power includes a charging voltage and a charging current;
wherein the current feedback signal is generated by comparing a current sensing signal relevant to the charging current with a current reference level, and the voltage feedback signal is generated by comparing a voltage sensing signal relevant to the charging voltage with a voltage reference level; and
a reference level adjustment procedure, including:
sensing a battery core voltage drop of a battery core inside the battery, thereby generating a battery core voltage drop sensing signal; and
generating an adjustment signal according to the battery core voltage drop sensing signal, so as to execute an adaptive adjustment of the voltage reference level.

9. The charging control method of claim 8, wherein the step of generating the adjustment signal according to the battery core voltage drop sensing signal, so as to execute the adaptive adjustment of the voltage reference level includes: adaptively lowering the voltage reference level when the battery core voltage drop sensing signal exceeds a predetermined threshold.

10. The charging control method of claim 9, wherein the step of adaptively lowering the voltage reference level when the battery core voltage drop sensing signal exceeds the predetermined threshold includes: adjusting a step signal to an ENABLE level when the battery core voltage drop sensing signal exceeds the predetermined threshold to indicate that the battery core voltage drop sensing signal exceeds the predetermined threshold, thereby lowering the voltage reference level by the predetermined difference.

11. The charging control method of claim 10, wherein the step of adaptively lowering the voltage reference level when the battery core voltage drop sensing signal exceeds the predetermined threshold further includes:
counting a time-out period when the step signal is at a DISABLE level which indicates the battery core voltage sensing signal does not exceed the predetermined threshold; and
generating an adjustment-ending signal at an end time point of the time-out period when the step signal is at the DISABLE level, so as to end the reference level adjustment procedure.

12. The charging control method of claim 10, wherein the step of adaptively lowering the voltage reference level when the battery core voltage drop sensing signal exceeds the predetermined threshold further includes: generating an adjustment-ending signal when the voltage reference level is not higher than a predetermined lower limit level, so as to end the reference level adjustment procedure.

13. The charging control method of claim 8, wherein the step of sensing the battery core voltage drop of the battery core inside the battery, thereby generating the battery core voltage drop sensing signal includes: converting the battery core voltage drop in analog form into the battery core voltage drop sensing signal in digital form.

14. The charging control method of claim 8, further including: setting an activation signal to an ENABLE level, so as to start up the reference level adjustment procedure.

15. The charging control method of claim 12, further including: setting the voltage reference level to the predetermined lower limit level when a protection signal is at a DISABLE level, so as to end the reference level adjustment procedure.

16. The charging control method of claim 10, wherein the step of adaptively lowering the voltage reference level when the battery core voltage drop sensing signal exceeds the predetermined threshold further includes: after the voltage reference level is lowered by the predetermined difference, maintaining the lowered voltage reference level for a predetermined period of time.

17. The charging control method of claim 8, wherein the power switch belongs to a power stage circuit, wherein the power stage circuit includes a switched inductive power stage circuit, a switched capacitive power stage circuit, a low dropout linear regulator or an AC/DC converter circuit.
